(19) United States
(12) Patent Application Publication
(10) Pub. No.: US 2007/0262379 A1
(43) Pub. Date: Nov. 15, 2007

(54) Metal structure of glass substrate and formation thereof

(76) Inventors: Chin-Chuan Lai, Padeh City (TW); Hsian-Kun Chiu, Padeh City (TW); Chuan-Yi Wu, Padeh City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/433,439

(22) Filed: May 15, 2006

(51) Int. Cl. H01L 27/12; H01L 27/01; H01L 31/0392

(52) U.S. Cl. 257/347

(57) ABSTRACT

Aluminum gate electrode parasitic resistance and capacitance delay suffers performance, and even makes the signal loss to high-resolution and small-size requests for thin film transistor liquid crystal display. An important technology employed in manufacturing thin film transistor is to convert surface of glass substrate into a silicon nitride layer, and subsequently to plate with one of low resistant copper, silver, copper alloy and silver alloy, and finally to form the thin film transistor on the substrate.

### BACKGROUND OF THE INVENTION

1. Field of the Invention

The invention relates to a thin film transistor and manufacturing, more especially, to a thin film transistor forming on a silicon nitride surface of glass substrate and the silicon nitride surface formation.

2. Background of the Related Art

Thin film transistor is a main technology in the thin film transistor liquid crystal display. FIG. 1 shows the sectional view of a thin film transistor on glass to illustrate the structure of the thin film transistor in prior art. The aluminum gate electrode 221 forms on the surface of the glass substrate 100, and induces the parasitic resistance delay, even the loss of the signal in large-scale and high-resolution thin film transistor liquid crystal display. In generally dual driving is employed to conquer the problem, but it does not solve it. To replace the aluminum with the low resistive material is the way.

The replacement of aluminum is one of silver, copper, copper alloy and silver alloy, but they do not easily adhere to the glass substrate. To enhance the adhesion is to form molybdenum layer on the glass substrate, and subsequently forms a copper layer on the molybdenum layer. FIG. 2 shows the structure of the thin film transistor with copper gate electrode. The buffer layer 223 made by molybdenum is formed between copper gate electrode 222 and the glass substrate 100. The structure induces an etching problem in manufacturing, that is, the different etching rate between copper and molybdenum destroys the shape of the gate electrode, even disables the thin film transistor. In generally the etching rate of copper is larger than that of molybdenum to make the etching hard.

How to treat the surface of the glass substrate to enhance the adhesion copper, silver or alloy of copper and silver is an important technology.

### SUMMARY OF THE INVENTION

One of objects of this invention is to enhance the adhesion between one of copper, silver, copper alloy and silver alloy. The technology is to form a silicon nitride layer on the glass substrate surface, and to plate with one of copper, silver, copper alloy and silver alloy to form a metallic layer on the silicon nitride layer, and subsequently to form the pattern of thin film transistor, and finally to complete the thin film transistor.

Another one of objects of this invention is to invert into silicon nitride on the glass substrate surface. The technology is to replace oxygen atom in the silicon oxide on the glass substrate surface with nitrogen atom to form a silicon nitride layer. The silicon nitride layer isolates and avoids one of copper ion and silver ion diffusing into the glass substrate.

According to the mentioned above, etching the metallic layer on glass substrate surface draws the gate electrode of thin film transistor, and subsequently forms the thin film transistor by conventional semiconductor process. It means to etch the metallic layer to form the gate electrode, and to cover the gate electrode with an isolative layer, semi conductive layer, and two discrete doping layers covered by metallic contacts as the electrodes, and to complete the thin film transistor.

### BRIEF DESCRIPTION OF THE DRAWINGS

FIG. 1 shows the sectional diagram illustrating a thin film transistor in prior art.

FIG. 2 shows the sectional diagram illustrating a thin film transistor in prior art.

FIG. 3 shows the sectional diagram illustrating the structure of the glass substrate according to an embodiment of this present invention.

FIG. 4 shows the flow chart illustrating the inverting the surface of the glass substrate to silicon nitride layer according to an embodiment of this present invention.

FIG. 5 shows the flow chart illustrating the inverting the surface of the glass substrate to silicon nitride layer according to an embodiment of this present invention.

FIG. 6 shows the sectional diagram illustrating a thin film transistor according to an embodiment of this present invention.

FIG. 7 shows the flow chart illustrating the manufacturing a thin film transistor according to an embodiment of this present invention.

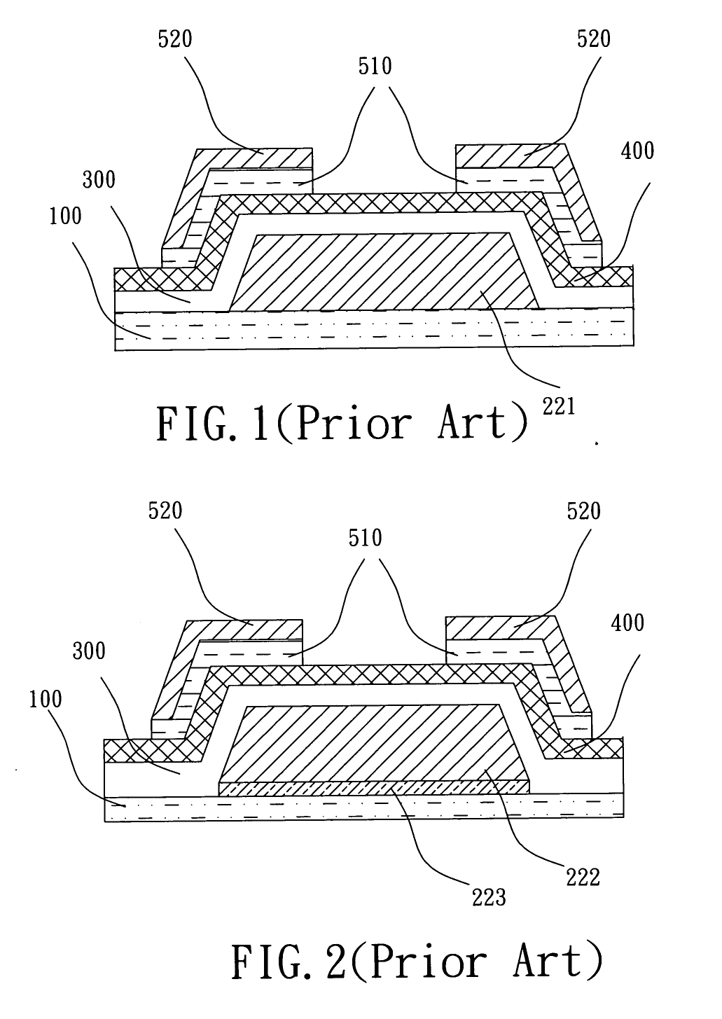

### DETAILED DESCRIPTION OF THE INVENTION

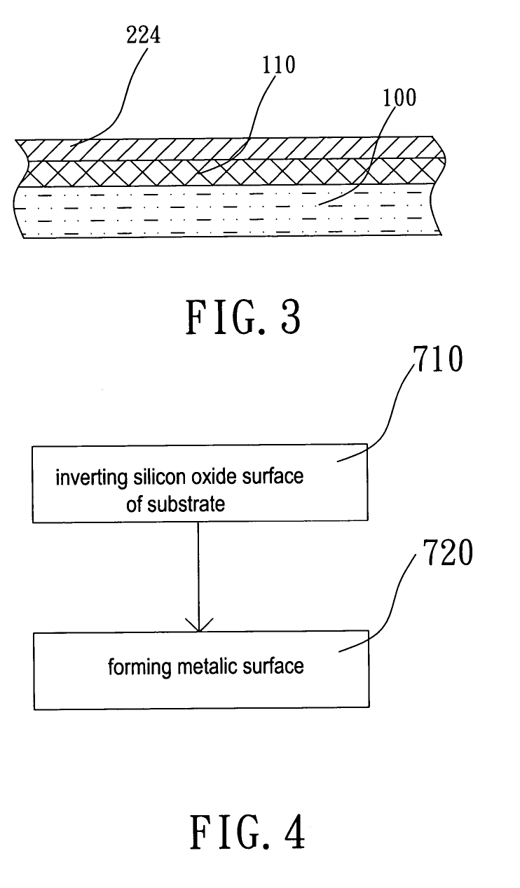

FIG. 3 shows the sectional diagram illustrating the structure of the glass substrate according to an embodiment of this invention. The bottom layer is the glass substrate 100, and the middle layer is a silicon nitride layer 110, and the top layer is the metallic layer 224. The metallic layer 224 is one of copper, silver, copper alloy and silver alloy, and the thickness of the silicon nitride layer is larger than 50 angstroms to avoid the electrical leakage and to obstruct copper or silver diffusing into the glass substrate.

FIG. 4 shows the flow chart illustrating the treatment of the surface of the glass substrate according to an embodiment of this invention.

Step 710 is to invert the surface of the glass substrate into a silicon nitride layer. To replace oxygen of the silicon oxide with nitrogen forms the silicon nitride layer on the glass substrate surface by plasma treatment or ion implementation by leading gases including the nitrogen, like ammonia, mixture of hydrogen and nitrogen or mixture of hydrogen and ammonia.

Step 720 is to form the metallic layer on the silicon nitride layer. Low resistance metal, like copper, silver, copper alloy and silver alloy, constructs the metallic layer, and the physical vapor deposition (noted PVD), metal organic chemical vapor deposition (MOCVD) or printing is employed.

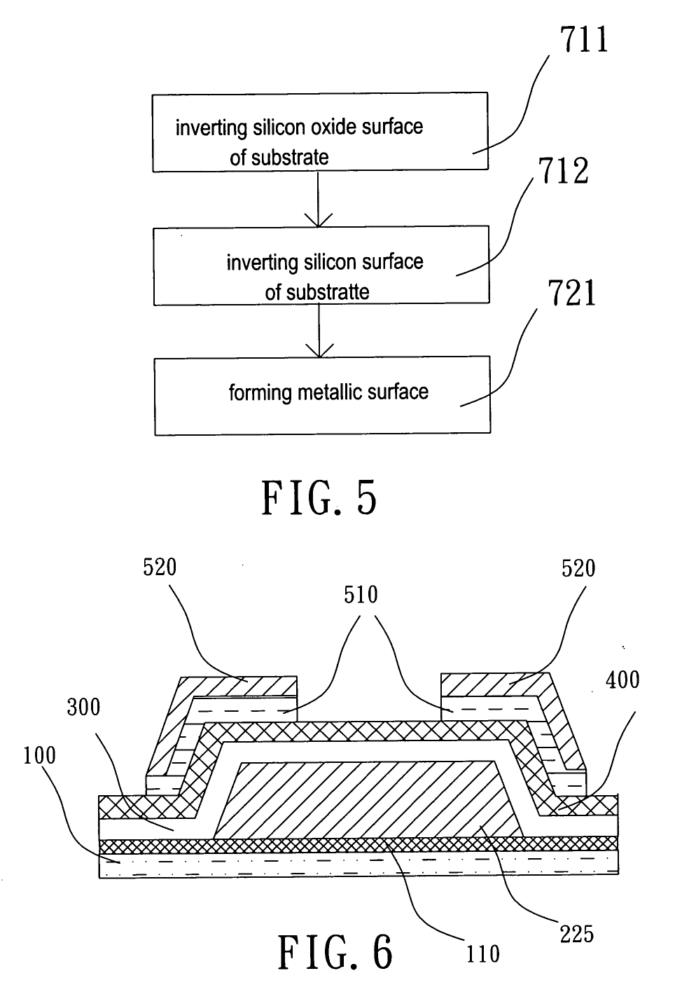

FIG. 5 shows the flow chart illustrating the treatment of the surface of the glass substrate according to another embodiment of this invention. It differs from the method mentioned above is first to invert the surface to a silicon layer, and subsequently to invert to a silicon nitride layer.

Step 711 is to invert the surface of the glass substrate into a silicon layer. The method is the plasma treatment or the ion implementation leading the gases including hydrogen, like hydrogen gases, mixture of hydrogen and nitrogen or mixture of hydrogen and ammonia to take the oxygen away from silicon oxide of the glass substrate.

Step 712 is to invert the silicon layer into a silicon nitride layer. The method is also the plasma treatment or the ion implementation leading the gases including nitrogen, like ammonia, mixture of hydrogen and nitrogen or mixture of hydrogen and ammonia.

Step 721 is to form the metallic layer on the silicon nitride layer. Low resistance metal, like copper, silver, copper ally and silver alloy, constructs the metallic layer, and the physical vapor deposition (PVD), metal organic chemical vapor deposition (MOCVD) or printing is employed.

Thin film transistor forms on the metallic layer by etching the metallic layer into the gate electrode of the thin film transistor. FIG. 6 shows the sectional diagram illustrating the structure of a thin film transistor according to an embodiment of this invention. The layers from bottom to top are a glass substrate 100, a silicon nitride layer 110, a gate electrode layer 225, an isolative layer 300, semi-conductive layer 400, two discrete doped layers 510 covered by metal electrodes 520 as the source and drain. Etching the metallic layer on the silicon nitride layer on glass substrate forms the gate electrode layer 225, and the material is one of copper, silver, copper alloy and silver alloy. The thickness of the silicon nitride layer 110 is larger than 50 angstroms to avoid the electrical leakage and the diffusion of the copper into the glass substrate 100.

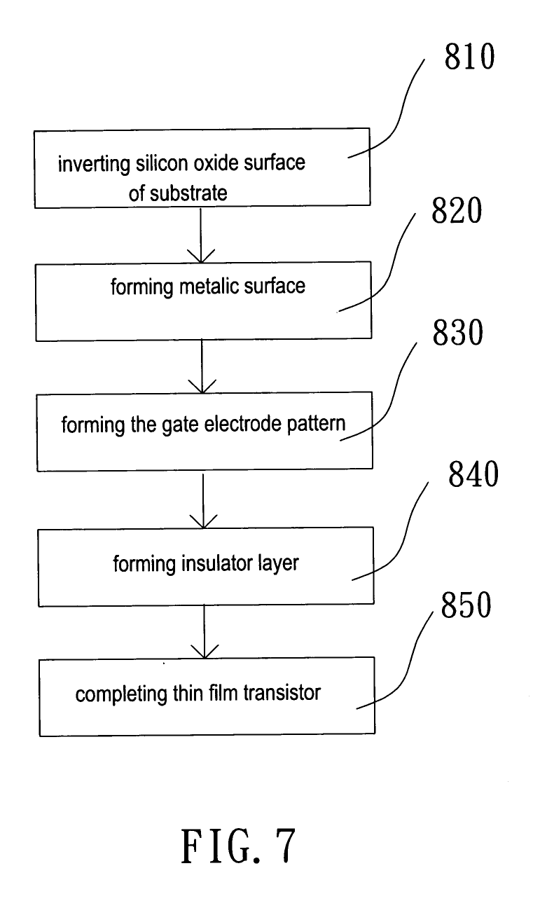

FIG. 7 shows the flow chart illustrating the formation of thin film transistor in as FIG. 6.

Step 810 is to invert the surface of the glass substrate into a silicon nitride layer. To replace oxygen of the silicon oxide with nitrogen forms the silicon nitride layer on the glass substrate surface by plasma treatment or ion implementation by leading gases including the nitrogen, like ammonia, mixture of hydrogen and nitrogen or mixture of hydrogen and ammonia.

Step 820 is to form the metallic layer on the silicon nitride layer. Low resistance metal, like copper, silver, copper alloy and silver alloy, constructs the metallic layer, and the physical vapor deposition (PVD), metal organic chemical vapor deposition (MOCVD) or printing is employed.

Step 830 is to draw the gate electrode according to the designed pattern, and in generally the method is the wet etching.

Step 840 is to form the isolative layer covering the gate electrode, and the layer would avoid electrical leakage.

Step 850 is to complete the manufacturing thin film transistor, that is, to stack and/or etch the rest layers of a thin film transistor, that is, to form the semi-conductive layer on the isolative layer, and to form two discrete doped layers covered by metallic electrodes as the source and drain electrode. In generally the doped layers are doped by the phosphor.

Basically the step 810 may be divided to two steps, first is to invert the silicon oxide into silicon layer and subsequently to silicon nitride layer.

Although the present invention has been explained in relation to its preferred embodiment, it is to be understood that other modifications and variation can be made without departing the spirit and scope of the invention as claimed.

1-3. (canceled)

4. A method to form a metallic layer on a glass substrate surface comprising:
inverting the glass substrate surface into a silicon nitride layer; and
forming a metallic layer on said silicon nitride layer, and said metallic layer is one of a layer of copper, silver, copper alloy and silver alloy.

5. The method to form a metallic layer on glass substrate surface in claim 4, wherein said inverting said glass substrate surface is first to invert said glass substrate layer into a silicon layer, and subsequently to invert said silicon layer into said silicon nitride layer.

6. The method to form a metallic layer on glass substrate surface in claim 5, wherein said inverting the glass substrate is a plasma treatment or an ion implementation.

7. The method to form a metallic layer on glass substrate surface in claim 6, wherein the leading gases in said plasma treatment or said ion implementation is ammonia, mixture of hydrogen and nitrogen or mixture hydrogen and ammonia.

8. The method to form a metallic layer on glass substrate surface in claim 4, wherein said forming the metallic layer is a physical vapor deposition, metal organic chemical vapor deposition or a printing.

9-13. (canceled)

14. A method manufacturing the thin film transistor comprising:
inverting a glass substrate surface into a silicon nitride layer;
forming a metallic layer on said silicon nitride layer, wherein said metallic layer is made by one of copper, silver, copper alloy and silver alloy;
forming a gate electrode by etching said metallic layer;
forming an isolative layer covering said gate electrode; and
completing the thin film transistor.

15. The method manufacturing the thin film transistor in claim 14, wherein said inverting said glass substrate surface into said silicon nitride layer is first to invert said glass substrate layer into a silicon layer, and subsequently to invert said silicon layer into said silicon nitride layer.

16. The method manufacturing the thin film transistor in claim 15, wherein said inverting the glass substrate is a plasma treatment or an ion implementation.

17. The method manufacturing the thin film transistor in claim 16, wherein the leading gases in said plasma treatment or said ion implementation is ammonia, mixture of hydrogen and nitrogen or mixture hydrogen and ammonia.

18. The method manufacturing the thin film transistor in claim 17, wherein said forming the metallic layer is a physical vapor deposition, metal organic chemical vapor deposition or a printing.

19. The method manufacturing the thin film transistor in claim 14, wherein said etching said gate electrode is wet etching.
